(19) United States
(12) Patent Application Publication
(10) Pub. No.: US 2007/0137999 A1
(43) Pub. Date: Jun. 21, 2007

(54) Method to reduce thermal stresses in a sputter target

(75) Inventors: Hilde Delrue, Mont-De-L'Enclus (BE); Ruben Vermeersch, Ursel (BE); Wilmert De Bosscher, Drongen (BE); Freddy Aps, Haasdonk (BE)

Correspondence Address: FOLEY AND LARDNER LLP;SUITE 500, 3000 K STREET NW, WASHINGTON, DC, 20007, US

(73) Assignee: BEKAERT ADVANCED COATINGS, Denize (BE)

(21) Appl. No.: 10/592,754

(22) PCT Filed: Mar. 11, 2005
(86) PCT No.: PCT/EP05/51115

§ 371 Date: Sep. 14, 2006

(30) Foreign Application Priority Data
Mar. 15, 2004 (EP) 04101044.8

(51) Int. Cl. C23C 14/32; C23C 14/00

(52) U.S. Cl. 204/192.1; 204/298.12

(57) ABSTRACT

The invention relates to a method to reduce thermal stresses in a sputter target during sputtering. The method provides the following steps providing a target holder, applying a target material comprising indium-tin-oxide on the target holder by spraying and introducing pores in the target material while applying the target material on the target holder. These pores leading to a porosity of at least 2% in the sprayed target material to reduce thermal stresses. The invention further relates to a sputter target having reduced thermal stresses and to a process for coating a substrate surface with indium-tin-oxide.

### FIELD OF THE INVENTION

The invention relates to a method to reduce the thermal stresses of a sputter target during sputtering.

The invention further relates to a sputter target, more particularly an indium-tin-oxide target having reduced thermal stresses.

### BACKGROUND OF THE INVENTION

During sputtering from a sputter target high thermal stresses can be created in the target material. These thermal stresses can result in debonding and cracking of the target material.

Indium-tin-oxide targets for example suffer from this problem.

The creation of thermal stresses is particularly accentuated when high power densities are applied during sputtering.

### SUMMARY OF THE INVENTION

It is an object of the present invention to provide a method to reduce the thermal stresses of a sputter target during target manufacturing and during sputtering.

It is another object of the invention to provide a sputter target having reduced thermal stresses during target manufacturing and during sputtering.

It is a further object to provide a process for coating a substrate at high power densities.

According to a first aspect of the present invention a method to reduce the thermal stresses in a sputter target during sputtering is provided.

The method comprises the following steps:
providing a target holder;
applying a target material comprising indium-tin-oxide on the target holder by spraying and introducing pores in the target material while applying the target material on the target holder.
The pores lead to a porosity of at least 2% in the applied target material to reduce thermal stresses.

The target material is applied by spraying, preferably by thermal spraying such as flame spraying, plasma spraying, high velocity oxygen fuel spraying or electric arc spraying.

More preferably, the porosity of the target material is higher than 4%, for example 10%.

The porosity of the target material is calculated as the percentage of the surface of the pores of a certain section on the total surface of this section.

The density of the target material is related to its porosity. The higher the porosity, the lower the density.

It is generally accepted in the art that high density (low porosity) targets are preferred over targets having a lower density (high porosity) as it is believed that high density targets result in an improved process stability (lower arc rate level). Therefore, several efforts have been made to increase the density of the target material.

During sputtering the back side of a sputter target, as for example the inner side of a tubular rotatable sputter target, is cooled. The cooling is for example water cooling. At the outside of the sputter target high temperatures are created. This results in a high temperature difference between the back side (inner side) and the outer side of the sputter target, creating high thermal stresses in the target material. The higher the sputter power density, the greater the temperature difference. According to the present invention, it has surprisingly been found that by using a sputter target having a minimum porosity of at least 2% the thermal stresses during sputtering are reduced.

Preferably, less than 20% of the pores formed in the target material comprises closed pores. More preferably, less than 10% of the pores formed in the target material comprises closed pores or even less than 5% of the pores formed in the target material comprises closed pores.

Open pores are pores that are in connection with the outer surface of the target material through a network of pores, grain boundaries, cracks or microcracks or through a mixture thereof.

Closed pores are pores that are not open to the outer surface of the target material.

To determine the amount of closed and open pores, a target material comprising indium-tin-oxide is impregnated with a fluorescent resin. To improve the penetration of the resin into the material, impregnation can be done in vacuum.

The amount of closed pores is then calculated as the percentage of the surface of the closed pores of a certain section on the total surface of the pores of this section.

Sputter targets comprising target material with a low percentage of closed pores and a high percentage of open pores are preferred as this type of sputter targets results in a more stable sputter process.

During the burn-in time of a sputter target having a target material with a low percentage of closed pores and a high percentage of open pores, the target material is not only cleaned but also degassed. This has as advantage that gas discharges are avoided once the sputtering is started and that a more stable sputter process is obtained.

Sputter targets having a high percentage of closed pores on the contrary may suffer considerable from gas explosions. Sputtering from this type of targers is at least at the beginning of the sputter process unstable.

The method according to the present invention is in particular suitable for target materials with reduced thermal conductivity.

The method is very suitable to be used for rotatable sputter targets, such as tubular sputter targets.

A preferred target comprises a target having as target material indium-tin-oxide, more particularly indium-tin-oxide sprayed on a target holder.

Indium-tin-oxide is one of the most used transparent conductive oxides in the thin film industry. Applications range from flat panel displays, smart windows, touch panels, electro-luminescent lamps to EMI shielding applications.

The target material can be applied starting from indium-tin-oxide powder. For the purpose of this invention indium-tin-oxide powder has to be understood as a mixture of oxides, such as indium oxide and tin oxide, or as a mixture of oxides and metals such as indium oxide and/or tin oxide and/or tin and/or indium.

The target material has preferably a concentration of tin ranging between 5 and 20 wt %. More preferably, the concentration of tin is between 5 and 15 wt %, for example 7, 10 or 20 wt %.

The hardness (micro Vickers hardness) of an indium-tin-oxide target according to the present invention is preferably between 200 and 400 HV, for example 250 HV.

The hardness of the target material is determined by micro Vickers hardness measurements whereby a typical micro Vickers diamond indenter is mounted on an ocular lens of an optical microscope. The microscope is used to determine the width of the indentation.

The hardness of the target material of a sputter target according to the present invention is lower than the hardness of a sputter target obtained by hot isostatic pressing.

This can be explained as follows:

During hot isostatic pressing, the powder particles are kept at a high temperature for a long time (e.g. 3 to 4 hours at 1000° C.). The combination of time and high temperature induces diffusion bonding between the separate particles and results in a strong interconnection of the particles.

Although the thermal spray process functions at temperatures that are equal or higher than during hot isostatic pressing, the diffusion reaction is minimal because of the very high cooling rates (typically 10⁶° C./sec). This minimal thermal interaction between the particles results in a predominantly mechanical interconnection. This mechanical binding offers the thermal sprayed structure more flexibility during hardness indentation, resulting in lower hardness values.

Furthermore, during hot isostatic pressing of a target material higher stresses are created in the target material compared to thermal sprayed targets and higher stresses result in a higher hardness.

This can be explained as follows:

During hot isostatic pressing, both target holder and target material are brought to high temperatures. The difference in thermal expansion between the target holder and the target material creates stresses in the target material during cooling in the hot isostatic pressing cycle.

The above-mentioned mechanism of stress build-up does not exist during thermal spraying as the target holder can be kept at low temperatures (e.g. 50° C.) during the thermal spray process.

By using sputter targets according to the present invention, characterized by a high porosity and a relatively low hardness, a high sputter rate can be obtained.

During the sputter process, the target material is bombarded with an ionized gas such as argon gas. Hence atoms are ejected from the target material and are deposited on the substrate to be coated.

As the interconnection between the individual particles of the target material of a target according to the present invention is less strong, the atoms of the target material are ejected more easily and the energy of the ionized gas can be used more efficiently so that a higher sputter rate can be obtained.

The pores have a size ranging between 1 μm² and 1000 μm², more preferably between 6 and 80 μm², for example between 6 and 40 μm².

Preferably, 50% of the pores have a pore size lower than 10 μm². A pore size of 10 μm² is believed to be a critical pore size for the creation of cracks in the target material and for the stability of the sputter process. The high amount of small pores in the target material of a sputter target according to the present invention is beneficial for the stress relaxation during target manufacturing and sputtering.

In ceramic targets such as indium-tin-oxide targets micro-cracks are present to a certain degree. These micro-cracks may result in serious cracks during sputtering because of the thermal stresses that are created.

In a target material according to the present invention the micro-cracks present in the target material are stopped at the interface target material/pore by the high number of small pores. In this way, the further growth of cracks due to the thermal stresses created during sputtering is stopped.

Crack growth is also hindered by the typical splat-like structure of thermal spraying: cracks predominantly propagate in the interface between two splats, further propagation can be hindered by another overlapping splat.

Furthermore, it is accepted that a sputter target having a target material with small pore sizes will exhibit a more stable sputter process, compared to a sputter target having a target material with big pore sizes. The latter may result in gas discharges during sputtering.

According to a second aspect of the invention a sputter target comprising a target holder and a target material is provided. The target material comprises indium-tin-oxide and is sprayed on the target holder. The target material has a porosity of at least 2%. More preferably, the target material has a porosity of at least 4%, for example 10% or 20%.

Preferably, less than 20% of the pores formed in the target material comprises closed pores.

More preferably, less than 10% or even less than 5% of the pores formed in the target material comprises closed pores.

A preferred sputter target according to the present invention comprises a rotatable sputter target, such as a tubular sputter target.

An indium-tin-oxide target according to the present invention has preferably a hardness ranging between 200 and 400 HV.

The target material of an indium-tin-oxide target has preferably pores having an average pore size between 1 μm² and 1000 μm², more preferably between 6 and 80 μm², for example between 6 and 40 μm². Preferably, 50% of the pores have a pore size lower than 10 μm². In this case, the high quantity of small pores spread in the target material is able to stop the growing of the cracks.

According to a further aspect of the invention a process for coating a substrate surface with indium-tin-oxide, by sputtering from a sputter target as described above is provided.

The process allows avoiding or reducing the creation of cracks in the target material.

The use of a sputter target according to the present invention allows that high power densities can be obtained during sputtering.

The power density is for example higher than 6 W/cm² race-track area, for example 8 W/cm² race-track area. Even at this high power density no cracks were created during the sputter process.

### DESCRIPTION OF THE PREFERRED EMBODIMENTS OF THE INVENTION

Some thermal sprayed indium-tin-oxide targets (table 1) are compared with some indium-tin-oxide targets obtained by hot isostatic pressing (table 2).

The sputter targets shown in table 1 all have a density between 5.8 and 6.6 g/cm³. The sputter targets shown in table 2 all have a porosity between 0.5 and 1.8%.

TABLE 1
Examples of thermal sprayed indium-tin-oxide sputter targets

| Examples according | Porosity | Hardness |
|---|---|---|
| to the invention | (%) | (HV) |
| 1 | 16.1 | 186 |
| 2 | 14.1 | 228 |
| 3 | 12.2 | 221 |
| 4 | 14.0 | 249 |
| 5 | 12.1 | 262 |
| 6 | 13.3 | 251 |
| 7 | 5.7 | 249 |
| 8 | 3.9 | 244 |

TABLE 2
Examples of indium-tin oxide sputter targets obtained by hot
isostatic pressing

| | Density | Hardness |
|---|---|---|
| Examples | (g/cm³) | (HV) |
| 9 | 6.85 | 487 |
| 10 | 6.8 | 488 |
| 11 | 6.7 | 490 |
| 12 | 6.99 | 486 |
| 13 | 7.00 | 500 |

From table 1 and table 2 it can be concluded that the thermal sprayed targets show a higher porosity, a lower density and a lower hardness than the indium-tin-oxide targets obtained by hot isostatic pressing.

A thermal sprayed tubular rotatable indium-tin-oxide target with a length of 1850 mm was used in a sputter process.

The sputter tests were performed at a power level up to 44 kW without creating cracks. Even at a power level of 50 kW, no cracks appeared.

1. A method to reduce thermal stresses in a sputter target during sputtering, said method providing the following steps:
providing a target holder;
applying a target material comprising indium-tin-oxide on said target holder by spraying and introducing pores in said target material while applying said target material on said target holder, said pores leading to a porosity of at least 2% in the applied target material to reduce thermal stresses.

2. A method according to claim 1, whereby said target material has a porosity of at least 4%.

3. A method according to claim 1, whereby less than 20% of the pores formed in the target material comprises closed pores.

4. A method according to claim 1, whereby less than 10% of the pores formed in the target material comprises closed pores.

5. A method according to claim 1, whereby said sputter target comprises a rotatable sputter target.

6. A method according to claim 1, whereby said target material has a hardness between 200 and 400 HV.

7. A method according to claim 1, whereby the pores of said target material have a size ranging between 1 and 1000 μm².

8. A method according to claim 1, whereby 50% of said pores have a pore size lower than 10 μm².

9. A sputter target comprising a target holder and a target material comprising indium-tin-oxide, said target material being sprayed on said target holder, said target material having a porosity of at least 2%.

10. A sputter target according to claim 9, whereby said target material has a porosity of at least 4%.

11. A sputter target according to claim 9, whereby less than 20 of the pores formed in said target material comprises closed pores.

12. A sputter target according to claim 9, whereby less than 10% of the pores formed in the target material comprises closed pores.

13. A sputter target according to claim 9, whereby said sputter target comprises a rotatable sputter target.

14. A sputter target according to claim 9, whereby said target material has a hardness between 200 and 400 HV.

15. A sputter target according to claim 9, whereby the pores of said target material have a size ranging between 1 and 1000 μm².

16. A sputter target according to claim 9, whereby 50% of the pores have a pore size lower than 10 μm².

17. A process for coating a substrate surface with indium-tin-oxide, by sputtering from a sputter target as defined in claim 9, said process allowing to avoid cracks in the target material of said sputter target.

18. A process according to claims 17, whereby said sputtering is performed at power densities higher than 6 W/cm² race track-area.
